(19) United States
(12) Patent Application Publication
(10) Pub. No.: US 2026/0173549 A1
(43) Pub. Date: Jun. 18, 2026

(54) NORMALLY-OFF JFET DEVICE

(71) Applicant: Analog Power Conversion LLC, Bend, OR (US)

(72) Inventors: Dumitru G. SDRULLA, Bend, OR (US); Nathaniel BARR, Bend, OR (US); Amaury GENDRON, Bend, OR (US)

(21) Appl. No.: 18/978,923

(22) Filed: Dec. 12, 2024

(51) Int. Cl. H10F 39/10; H10H 29/10

(52) U.S. Cl. CPC H10F 39/103; H10H 29/10

(57) ABSTRACT

A semiconductor device comprises a control terminal, a first conduction terminal, a second conduction terminal, a normally-on transistor, and an optoelectronic circuit. The normally-on transistor is electrically coupled between the first and second conduction terminals and is configured to control a current through the first and second conduction terminals according to a signal on a control terminal of the normally-on transistor. The optoelectronic circuit comprising one or more current-generating photoelectric devices electrically connected in series between the control terminal of the semiconductor device and the control terminal of the normally-on transistor, and configured to generate, in response to the current-generating photoelectric devices being illuminated, a bias voltage sufficient to turn off the normally-on transistor. The normally-on transistor may be a junction field effect transistor (JFET) or a static induction transistor (SIT) comprising a wide-bandgap semiconductor. The semiconductor device may be operable at an ambient temperature of 550° C.

### BACKGROUND

Junction Field Effect Transistors (JFETs) and Static Induction Transistors (SITs) are depletion-mode devices that are normally on; that is, a negative voltage (relative to the source of the device) must be applied to the gate of the device to turn the device off. Therefore, if no signal is applied to the gate of the device, the device is on and current is able to flow between the conduction terminals (i.e. the source and drain) of the device.

In contrast, normally-off devices, such as enhancement-mode Metal-Oxide-Semiconductor FETs (MOSFETs) do not allow current to flow between the conduction terminals of the device when there is no signal on the gate of the normally-off device.

As a result, if circuits providing the gate voltage of a JFET or SIT malfunction or lose power, the JFET or SIT will be stuck on, which may have disastrous consequences. For example, when the JFET or SIT is a power transistor of a switching converter circuit, a short may be created across the power supply of that circuit.

Accordingly, it would be advantageous to have a JFET or SIT that was normally-off, so that a failure that leaves the gate of the JFET or SIT without a signal does not risk a catastrophic failure. Furthermore, it would be advantageous if such a JFET or SIT could operate at elevated ambient temperatures.

### SUMMARY OF THE INVENTION

Embodiments relate to semiconductor devices, and in particular to JFETs or SITs that include photoelectric components that cause the JFET or SIT to operate as a normally-off device.

In an embodiment, a semiconductor device comprises a control terminal, a first conduction terminal, a second conduction terminal, a normally-on transistor, and an optoelectronic circuit. The normally-on transistor is electrically coupled between the first and second conduction terminals and is configured to control a current through the first and second conduction terminals according to a signal on a control terminal of the normally-on transistor. The optoelectronic circuit comprising one or more current-generating photoelectric devices electrically connected in series between the control terminal of the semiconductor device and the control terminal of the normally-on transistor, and configured to generate, in response to the current-generating photoelectric devices being illuminated, a bias voltage sufficient to turn off the normally-on transistor.

In embodiments, the normally-on transistor may be a junction field effect transistor (JFET) or a static induction transistor (SIT).

In embodiments, the optoelectronic circuit comprises and one or more light-emitting devices optically coupled to the one or more current-generating photoelectric devices and configured to illuminate the one or more current-generating photoelectric devices.

In an embodiment, one or more of the normally-on transistor, the current-generating photoelectric devices, the light-emitting devices may comprise respective wide-bandgap semiconductors.

In an embodiment, the semiconductor device may be operable at an ambient temperature of 550° C.

### BRIEF DESCRIPTION OF THE DRAWINGS

FIG. 1A is a conceptual schematic of circuit including a generalized normally-off JFET.

FIG. 1B includes a conceptual schematic of a normally-off JFET according to an embodiment.

FIG. 2 includes a schematic of a normally-off JFET according to an embodiment.

FIG. 3A includes a schematic of a normally-off JFET according to an embodiment.

FIG. 3B includes a schematic of a normally-off JFET according to an embodiment.

FIG. 3C includes a schematic of a normally-off JFET according to an embodiment.

FIG. 4 includes a schematic of a normally-off JFET according to an embodiment.

FIG. 5 is a plan view of a normally-off JFET according to an embodiment.

FIG. 6 is a plan view of a normally-off JFET according to an embodiment.

FIG. 7 is a section view of a normally-off JFET according to an embodiment.

FIG. 8 is a section view of a normally-off JFET according to an embodiment.

### DETAILED DESCRIPTION

Embodiments of the present application relate to optoelectronic circuits that may be integrated with a normally-on device to cause the device to operate as a normally-off device, and in particular to a circuit or device including a JFET or SIT, one or more photodiodes, and one or more light-emitting diodes so that the circuit or device operates as a normally-off JFET or SIT.

A detailed description of embodiments is provided below along with accompanying figures. The scope of this disclosure is limited only by the claims and encompasses numerous alternatives, modifications, and equivalents. Although steps of various processes may be presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

Embodiments are disclosed that incorporate a normally-on JFET, but embodiments are not limited thereto, a person of ordinary skill in the art would understand that other kinds of normally-on devices may be used instead of a normally-on JFET.

Embodiments are disclosed that have an N-type drift layer, but embodiments are not limited thereto and may instead have a P-type drift layer. A person of ordinary skill in the art would understand that in an embodiment having a P-type drift layer, elements would generally having an opposite doping (where P and N are considered opposites) than shown in the embodiments disclosed herein.

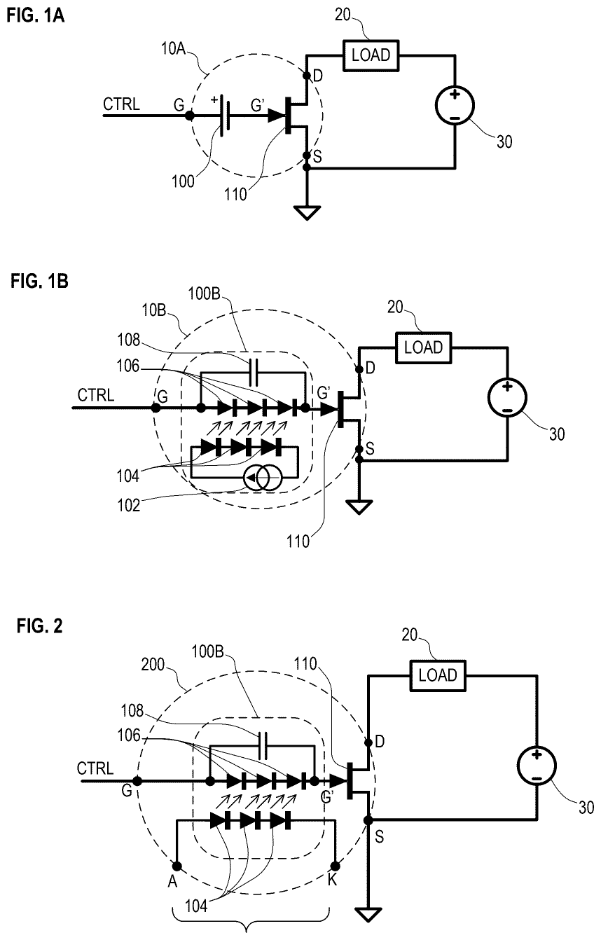

FIG. 1A is a conceptual schematic of circuit including a generalized normally-off JFET 10A. The normally-off JFET 10A comprises a normally-on JFET 110 and a voltage source 100. In embodiments, the normally-off JFET 10A and the normally-on JFET 110 are fabricated using a wide bandgap semiconductor such as silicon carbide (SiC), but embodiments are not limited thereto. In the illustrated embodiments, the normally-off JFET 10A and the normally-on JFET 110 are both n-channel devices, but embodiments are not limited thereto.

The normally-off JFET 10A modulates a current flowing between its drain D and source S in response to the voltage applied to its gate G′. The normally-on JFET 110 modulates the conductivity between its drain and source according to a signal on its gate G′ to control the current between the drain D and source S of the normally-off JFET 10A. In the illustrated circuit, the current flows from a power supply 30 through a load 20

A drain and a source of the normally-on JFET 110 are respectively electrically coupled to the drain D and S source of the normally-off JFET 10A. In embodiments, the normally-on JFET 110 is a power JFET or a SIT, a high-voltage JFET or a SIT, or a high-voltage power JFET or a SIT.

The signal on the gate G′ of the normally-on JFET 110 is generated by summing the voltage of the voltage source 100 with a control signal CTRL supplied to the gate G of the normally-off JFET 10A. The voltage of the voltage source 100 is greater than the magnitude of the pinch-off voltage of the normally-on JFET 110. As an illustrative example, in an embodiment wherein the normally-on JFET 110 is an n-channel JFET having a pinch-off voltage of −11.5 volts, the voltage across the voltage source 100 may be 19 volts, which results in the effective threshold voltage of the normally-off JFET 10A being 7.5 volts.

As a result, when a signal having a ground level is supplied to the gate G of the normally-off JFET 10A, the voltage drop across the voltage source 100 is presented to the gate G′ of the normally-on JFET 110 which turns the normally-on JFET 110 off, so that the normally-off JFET 10A is off. As the illustrative example presented above, the normally-off JFET 10A will be off unless a voltage greater than its effective threshold voltage of 7.5 volts is supplied to its gate G.

FIG. 1B includes a conceptual schematic of a normally-off JFET 10B according to an embodiment. In the normally-off JFET 10B, the voltage source 100 of FIG. 1A is implemented by a voltage source 100B.

The voltage of the voltage source 100B is generated by one or more photodiodes 106 connected in series in photovoltaic mode. The number, illumination, and material of photodiodes 106 determines the voltage across the voltage source 100B.

In the voltage source 100B, the one or more photodiodes 106 are illuminated by one or more light emitting diodes (LEDs) 104, but embodiments are not limited thereto. The number of LEDs 104 may be determined by the amount of illumination needed on the photodiodes 106, the need to illuminate all of the photodiodes 106 according to their physical configuration, or a combination thereof.

Although FIG. 1B shows the LEDs 104 electrically connected in series, embodiments are not limited thereto, and in embodiments the one or more LEDs 104 may comprise a plurality of LEDs connected in series, a plurality of LEDs connected in parallel, or combinations thereof according to the physical requirements for illuminating the photodiodes 106 and the electrical characteristics of the LEDs and the source of current to the LEDs. For example, when the one or more photodiodes 106 comprises two sets of photodiodes that are physically separated from each other, the LEDs 104 may comprise two series-connected strings of LEDs that are physically separated from each other in order to illuminate respective strings of photodiodes and that are electrically connected in parallel, wherein the number of LEDs in each series connected string may be determined according to the characteristics of the source of power for the LEDs s as would be understood by a person of ordinary skill in the related arts.

A current source 102 supplies the LEDs 104 with the current needed to provide sufficient illumination to the photodiodes 106. The current source 102 is shown in FIG. 1B as being internal to the normally-off JFET 10B, but embodiments are not limited thereto.

The voltage source 100B may further include a capacitor 108 that reduces noise in the voltage of the voltage source, improves high-frequency performance, and when the control signal CTRL switches operates as a charge pump in concert with the gate-source junction of the normally-on JFET 110 to aid in startup of the device. In embodiments, the capacitor 108 is integrated into the same semiconductor substrate as normally-on JFET 110 using standard CMOS technology (e.g. polysilicon on oxide, metal-insulator-metal, and so on.)

In embodiments, the photodiodes 106 may be fabricated in the same semiconductor substrate as the normally-on JFET 110. In embodiments, the LEDs 104 may also be fabricated in the same semiconductor substrate as the normally-on JFET 110. For example, in an embodiment wherein the normally-on JFET 110 is a SiC JFET fabricated on a SiC substrate, the photodiodes 106 and LEDs 104 may be SiC photodiodes and LEDs, respectively, fabricated on the SiC substrate.

However, in other embodiments wherein the normally-on JFET 110 is made of an indirect-bandgap semiconductor (as SiC is), to improve the efficiency of the normally-off JFET 10B, the LEDs 104 may be fabricated of a direct-bandgap semiconductor. In some embodiments, the photodiodes 106 may be made of the same semiconductor as the normally-on JFET 110 or of a different semiconductor.

For example, in an embodiment wherein the normally-on JFET 110 is fabricated on a SiC substrate, the LEDs 104 and photodiodes 106 may be fabricated on a gallium nitride (GaN) substrate. In embodiments, the GaN substrate may then be mounted on the SiC substrate. In an embodiment wherein the LEDs 104 and photodiodes 106 are fabricated on GaN or SiC and the JFET 110 is fabricated on a SiC substrate, the JFET 110 may be capable of sustained operation at high temperatures. For example, such an embodiment may be able to operate reliably at ambient temperatures of up to 550° C.

FIG. 2 includes a schematic of a normally-off JFET 200 according to an embodiment. The normally-off JFET 200 is distinguished from the normally-off JFET 100B of FIG. 1B in that the current source 102 shown in the normally-off JFET 100B is not shown in FIG. 2.

Instead, current is supplied to the LEDs 104 via the LED anode A and LED cathode K terminals of the normally-off JFET 200.

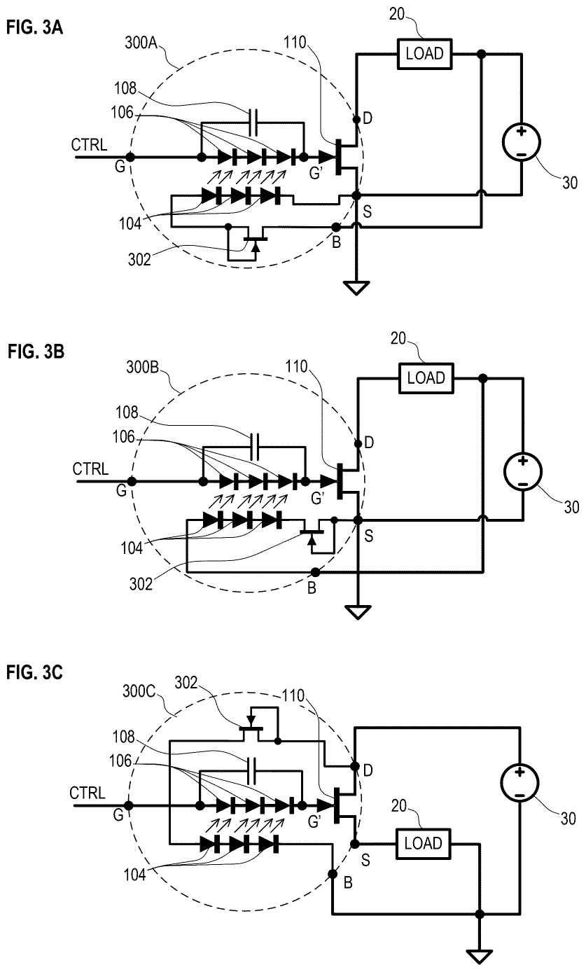

In embodiments, a JFET such as the JFET 302 described with respect to FIGS. 3A through 3B, below, may be incorporated in series with the LEDs 104 to control the amount of current delivered to the LEDs 104.

FIG. 3A includes a schematic of a normally-off JFET 300A according to an embodiment. The normally-off JFET 300A is distinguished from the normally-off JFET 100B of FIG. 1B in that the current source 102 shown in the normally-off JFET 100B is implemented using a JFET 302.

The JFET 302 is sized to produce an appropriate current through the LEDs 104. In embodiments, the JFET 302 is fabricated on the same semiconductor substrate as the normally-on JFET 110.

In the embodiment of FIG. 3A, the JFET 302 receives, through a bias terminal B of the normally-off JFET 300A, a voltage from the same power supply 30 that powers the load 20. Using the power supply 30 as the source of the current for the LEDs 104 eliminates the risk that a failure of the power supply for the current for the LEDs 104, which would cause the normally-off JFET 300A to revert to operating as normally-on, would lead to uncontrolled current flow through the load 20.

FIG. 3B includes a schematic of a normally-off JFET 300B according to an embodiment. The normally-off JFET 300B is distinguished from the normally-off JFET 300A in the placement of the JFET 302 in the circuit including the LEDs 104. A person of ordinary skill in the art would understand that the JFET 302 could be connected before (relative to the current flow), after, or in the middle of the string of series-connected LEDs 104.

FIGS. 3A and 3B illustrate normally-off JFETs 300A and 300B suitable for use as low-side switching devices. FIG. 3 illustrates a normally-off JFET 300C for use as a high-side switching device.

The normally-off JFET 300C differs from the normally-off JFET 300A of FIG. 3A in that instead of the cathode of the LEDs 104 being tied to the source terminal S, the cathode of the LEDs 104 are tied to a bias terminal B′. Furthermore, instead of the anodes of the LEDs 104 being coupled to the bias terminal through the JFET 302, the anodes of the LEDs 104 are coupled to the drain D of the normally-off JFET 300C through the JFET 302.

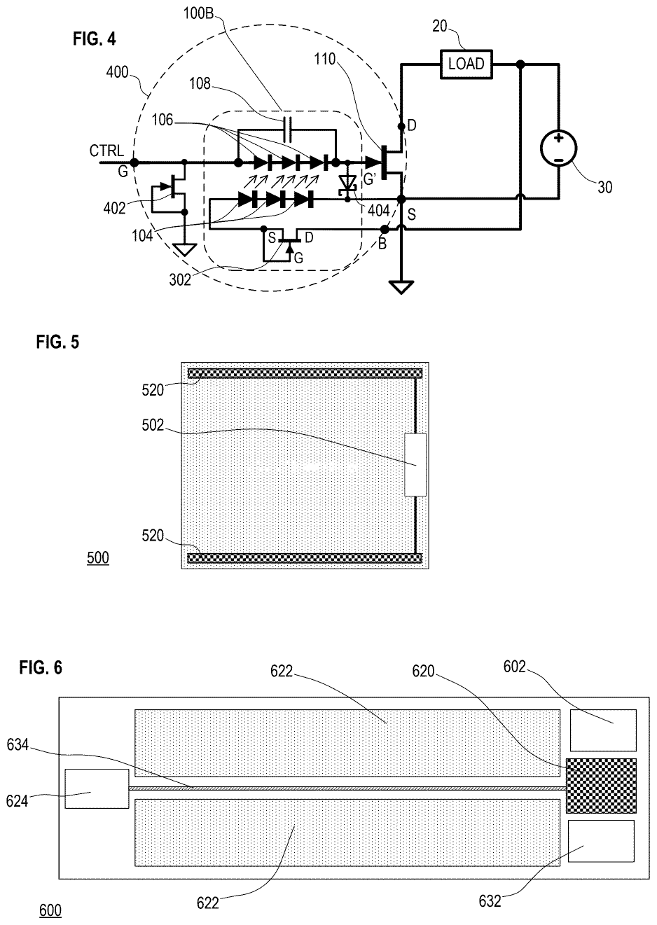

FIG. 4 includes a schematic of a normally-off JFET 400 according to an embodiment. The normally-off JFET 400 differs from the normally-off JFET 300A of FIG. 3A by including protection devices.

Specifically, the normally-off JFET 400 includes a pull-down 402 on the gate input G, here provided (for processing simplicity) using a JFET which may be fabricated in the same substrate as the normally-on JFET 110. The pull-down 402 ensures that if an open circuit occurs on the gate input G, the normally-off JFET 400 will turn off. The JFET used in the pull-down 402 should have a low I_{DSS} and does not need to be rated to handle high voltages.

The normally-off JFET 400 also includes a Schottky diode 404 coupled between the gate G′ and the source of the normally-on JFET 110 to protect the gate of the normally-on JFET 110 from overvoltage or excessive current input. The Schottky diode 404 may be fabricated in the same substrate as the normally-on JFET 110.

FIG. 5 is a plan view of a normally-off JFET 500 showing an arrangement of components of the according to an embodiment. The normally-off JFET 500 comprises a vertical JFET having a source and gate pads on a top surface and a drain pad on a bottom surface. The normally-off JFET 500 comprises a normally-on JFET corresponding to the normally-on JFET 110 of FIGS. 2-4.

One or more optoelectronic portions 520 (here, two) are disposed on the normally-off JFET 500. Each optoelectronic portion 520 includes one or more photodiodes corresponding to photodiode 106 of FIGS. 2-4 and one or more LEDs corresponding to LEDs 104 of FIGS. 2-4 where the LEDs of each optoelectronic portion 520 are optically coupled to the photodiodes of that optoelectronic portion 520.

In embodiments, the photodiodes, the LEDs, or both of each optoelectronic portion 520 may be fabricated in the same semiconductor substrate as the normally-on JFET of normally-off JFET 500. In other embodiments, the photodiodes, the LEDs, or both of each optoelectronic portion 520 may be fabricated in a different semiconductor substrate than the normally-on JFET of normally-off JFET 500.

The normally-off JFET 500 further includes a JFET 502 corresponding to the JFET 302 used to regulate the current to the LEDs in the one or more optoelectronic portions 520. In embodiments, the JFET 502 may be fabricated in the same semiconductor substrate as the normally-on JFET of normally-off JFET 500.

FIG. 6 is a plan view of a normally-off JFET 600 according to an embodiment. The normally-off 600 comprises a vertical JFET having source pads 622 and a gate pad 624 on a top surface and a drain pad (not shown) on a bottom surface. The normally-off JFET 600 comprises one or more normally-on JFETs corresponding to the normally-on JFET 110 of FIGS. 2-4.

The source pads 622 correspond to the source S of the normally-off JFET shown in FIGS. 2 through 4 and are connected to the sources S of the one or more normally-on JEFTs corresponding to the normally-on JFET 110. The gate pad 624 corresponds to the Gate S of the normally-off JFET shown in FIGS. 2 through 4.

One or more optoelectronic portions 620 (here, one) are disposed on the normally-off JFET 600. The optoelectronic portions 620 correspond to the optoelectronic portions 520 of FIG. 5 and accordingly a description thereof is omitted for brevity.

The normally-off JFET 600 further includes a JFET 602 corresponding to the JFET 502 used to regulate the current to the LEDs in FIG. 5, and accordingly a description thereof is omitted for brevity.

The normally-off JFET 600 further includes a pull down 632 which may be implemented using a JFET as described for the pull down 402 of FIG. 4, and accordingly a description thereof is omitted for brevity.

FIG. 6 shows an electrical connection 634 between the gate pad 624 and the anode end of the photodiodes incorporated in the optoelectronic portions 620. Another electrical connection (not shown) connects the cathode end of the photodiodes incorporated in the optoelectronic portions 620 to the gate of the one or more normally-on JEFTs (corresponding to the normally-on JFET 110 of FIGS. 2-4) in the normally-off JFET 600.

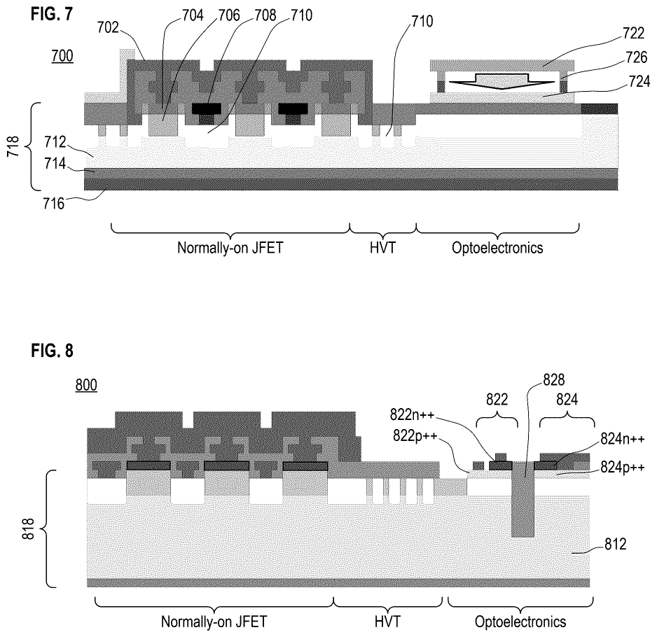

FIG. 7 is a section view of a normally-off JFET 700 according to an embodiment. The normally off JFET 700 comprises a normally-on JFET corresponding to the normally-on JFET 110 of FIGS. 2-4, a high voltage termination (HVT) disposed around the normally-on JFET, and optoelectronics corresponding to the voltage source 100B of FIGS. 1B through 4. The normally-on JFET and the HVT are fabricated on a semiconductor substrate 718, which may be, for example a silicon carbide substrate.

The normally-on JFET comprises a source electrode 702, n++ doped source regions 704, n-doped channel regions 706, gate electrodes 708, p-wells 710, n-doped drift later 712, n-doped drain contact layer 714, and drain electrode 716, and may include other features as are known in the art.

The high voltage termination comprises one or more p-wells 710 and may include other features as are known in the art.

The optoelectronics comprises an LED component 722, a photodiode component 724, and support interconnects 726 that mechanically and electrically connect the LED component 722 to remainder of the normally off JFET 700. The support interconnects 726 may include copper pillars, solder bumps, or other such structures as are known in the art, or combinations thereof.

The LED component 722 comprises one or more LEDs physically arranged to illuminate photodiodes in the photodiode component 724, as shown by the arrow in FIG. 7. In the embodiment of FIG. 7, the LED component 722 is fabricated on a different semiconductor substrate than the semiconductor substrate 718. In embodiments, the semiconductor substrate used for the LED component 722 may be comprise a direct-bandgap semiconductor.

The photodiode component 724 comprises one or more photodiodes physically arranged to be illuminated by the LEDs of the LED component 722. In the embodiment of FIG. 7, the photodiode component 724 is fabricated on a different semiconductor substrate than the semiconductor substrate 718. In embodiments, the semiconductor substrate used for the photodiode component 724 may be a direct-bandgap semiconductor.

A front metal layer of the photodiode component 724 is configured to allow connection of a plurality of photodiodes in the photodiode component 724 is series in order to generate the necessary voltage for keeping the normally-on JFET off in the absence of a voltage at the gate G of the normally-off JFET 700. The front metal layer may also be configured to allow connection of respective one or more photodiodes in a plurality of photodiode components 724 is series in order to generate the necessary voltage.

While FIG. 7 shows the LED component 722 and the photodiode component 724 as being fabricated on separate respective substrates, embodiments are not limited thereto. In another embodiment, the LED component 722 and the photodiode component 724 are fabricated on a same semiconductor substrate (different from the semiconductor substrate 718) and optically coupled in a manner similar to that shown in FIG. 8, below.

FIG. 8 is a section view of a normally-off JFET 800 according to an embodiment. The normally off JFET 800 comprises a normally-on JFET corresponding to the normally-on JFET 110 of FIGS. 2-4, a high voltage termination (HVT) disposed around the normally-on JFET, and optoelectronics corresponding to the voltage source 100B of FIGS. 1B through 4. The normally-on JFET, the HVT, and the optoelectronics are fabricated on a semiconductor substrate 818, which may be, for example, a silicon carbide substrate.

The normally-on JFET and HVT of the normally-off JFET 800 may be substantially similar to the normally-on JFET and HVT of the normally-off JFET 700 of FIG. 7, and so a detailed description of them is omitted in the interest of brevity.

The optoelectronics comprise an LED component 822 and a photodiode component 824 optically coupled together through a trench 828 disposed between them. The trench 828 comprises a material, such as a dielectric material, that is substantially transparent to light at the wavelengths emitted by the LED component 822.

The LED component 822 comprises one or more LEDs physically arranged to illuminate photodiodes in the photodiode component 824. The LEDs of the LED component 822 comprise one or more n++ doped regions 822n++ that operate as cathodes (which may be substantially similar to and fabricated at the same time as the n++ doped source regions of the normally-on JFET) and one or more p++ doped layers 822p++ that operate as cathodes. In FIG. 8, the n++ doped regions 822n++ are shown disposed on top of the p++ doped layers 822p++, but embodiments are not limited thereto, and in other embodiments the p++ doped layers 822p++, may be disposed on top of the n++ doped regions 822n++.

The photodiode component 824 comprises one or more photodiodes physically arranged to be illuminated by the LEDs of the LED component 822. The one or more photodiodes may comprise one or more n++ doped regions 824n++ that operate as cathodes and one or more p++ doped layers 824p++ that operate as cathodes.

A front metal layer of the photodiode component 824 is configured to allow connection of a plurality of photodiodes in the photodiode component 824 is series in order to generate the necessary voltage for keeping the normally-on JFET off in the absence of a voltage at the gate G of the normally-off JFET 800. The front metal layer may also be configured to allow connection of respective one or more photodiodes in a plurality of photodiode components 824 is series in order to generate the necessary voltage.

Because, as demonstrated in FIG. 8, the photoelectric components of a normally-off JFET or SIT according to an embodiment may be fabricated using materials capable of operating at high temperatures, embodiments may operate at high temperatures. For example, an embodiment including a SiC JFET or SIT and SiC LEDs and photodiodes may be capable of operating reliably at ambient temperatures of 550° C.

Embodiments provide a device that operates as a normally-off JFET by incorporating a photoelectric circuit that provides of bias voltage between a gate input of the device and a gate input of a normally-on JFET of the device. Embodiments may do so illuminating, using one or more light emitting devices (such as a plurality of LEDs), one or more current-generating photoelectric devices (for example, a plurality of photodiodes) to electrically couple between the gate input of the device and a gate input of a normally-on JFET.

In other embodiments, a device is provided that operates as a normally-off SIT by incorporating the photoelectric circuit that provides of bias voltage between a gate input of the device and a gate input of a normally-on SIT of the device. Generally, wherever a JFET is mentioned in this disclosure, a SIT could be used instead.

Embodiments are relatively simple and unlike some alternative approaches may be operated at high temperature and for extended periods of time without needing periodic replacement of components.

The normally-on JFET may be a power JFET so that the device operates as a normally-off power JFET. The normally-on JFET may be a silicon carbide (SiC) device.

In some embodiments, the photoelectric circuit provides isolation between the source of power for the light emitting devices and the power being supplied to a load controlled by the normally-off JFET device. In other embodiments, the light emitting devices may be powered by the same source of power as the load controlled by the normally-off JFET device so that a failure of power to the light emitting devices does not result in a dangerous malfunction due to the loss of the normally-off characteristics of the normally-off JFET device.

In embodiments, the current-generating photoelectric devices, the light emitting devices, or both may be fabricated in the same semiconductor substrate as the normally-on JFET of the device for ease of fabrication.

In other embodiments, the current-generating photoelectric devices, the light emitting devices, or both may be fabricated on a different semiconductor substrate than the normally-on JFET of the device. For example, when the normally-on JFET of the device is fabricated of SiC, the current-generating photoelectric devices, the light emitting devices, or both may be fabricated on a semiconductor substrate having improved photoelectric efficiency (such as a direct-bandgap semiconductor such as gallium nitride).

Aspects of the present disclosure have been described in conjunction with the specific embodiments that are presented as illustrative examples, but embodiments are not limited to those shown in the drawings or those mentioned in the accompanying text. Numerous alternatives, modifications, and variations to the disclosed embodiments may be made without departing from the scope of the claims set forth below. Embodiments disclosed herein are not intended to be limiting.

What is claimed is:

1. A semiconductor device comprising:
a control terminal;
a first conduction terminal;
a second conduction terminal;
a normally-on transistor electrically coupled between the first and second conduction terminals and configured to control a current through the first and second conduction terminals according to a signal on a control terminal of the normally-on transistor; and
an optoelectronic circuit comprising one or more current-generating photoelectric devices electrically connected in series between the control terminal of the semiconductor device and the control terminal of the normally-on transistor, and configured to generate, in response to the current-generating photoelectric devices being illuminated, a bias voltage sufficient to turn off the normally-on transistor.

2. The semiconductor device of claim 1, wherein the normally-on transistor is a junction field effect transistor (JFET).

3. The semiconductor device of claim 1, wherein the normally-on transistor is a static induction transistor (SIT).

4. The semiconductor device of claim 1, wherein the normally-on transistor comprises a wide-bandgap semiconductor.

5. The semiconductor device of claim 1, wherein the one or more current-generating photoelectric devices comprises one or more photodiodes.

6. The semiconductor device of claim 1, wherein the optoelectronic circuit further comprises one or more light-emitting devices optically coupled to the one or more series-connected current-generating photoelectric devices and configured to illuminate the one or more current-generating photoelectric devices.

7. The semiconductor device of claim 6, further comprising a bias terminal, wherein the one or more light-emitting devices are electrically connected between the bias terminal and the second conduction terminal.

8. The semiconductor device of claim 6, further comprising a first bias terminal and a second bias terminal, wherein the one or more light-emitting devices are electrically connected between the first and second bias terminals.

9. The semiconductor device of claim 6, further comprising a current regulating circuit electrically connected in series with the one or more light-emitting devices.

10. The semiconductor device of claim 6, wherein the one or more light-emitting devices comprise one or more light-emitting diodes.

11. The semiconductor device of claim 6, wherein the one or more light-emitting devices are fabricated in a same semiconductor substrate as the normally-on transistor.

12. The semiconductor device of claim 6, wherein the one or more light-emitting devices are fabricated in a same semiconductor substrate as the one or more current-generating photoelectric devices.

13. The semiconductor device of claim 6,
wherein the normally-on transistor comprises a first wide-bandgap semiconductor,
wherein the one or more current-generating photoelectric devices comprise a second wide-bandgap semiconductor,
wherein the one or more light-emitting devices comprise a third wide-bandgap semiconductor, and
wherein the semiconductor device is capable of reliably operating at an ambient temperature of 550° C.

14. The semiconductor device of claim 1, wherein the one or more current-generating photoelectric devices are fabricated in a same semiconductor substrate as the normally-on transistor.

15. The semiconductor device of claim 1, further comprising a pull-down circuit electrically coupled between the control terminal of the device and one of the first and second conduction terminals of the device.

16. The semiconductor device of claim 15, wherein the pull-down circuit is fabricated on a same semiconductor substrate as the normally on transistor.

17. The semiconductor device of claim 1, further comprising a Schottky diode electrically connected between the control terminal of the normally-on transistor and one of the first and second conduction terminals of the device.

18. The semiconductor device of claim 17, wherein the Schottky diode is fabricated on a same semiconductor substrate as the normally on transistor.

19. A method of providing a normally-off transistor, the method comprising:
generating across a string comprising a plurality of series-connected current-generating photoelectric devices a bias voltage by illuminating the plurality of series-connected current-generating photoelectric devices;
providing an input signal to a first end of the string; and
providing an output signal corresponding to a combination of the input signal and the bias voltage from a second end of the string to a normally-on transistor,
wherein the bias voltage is sufficient to turn off the normally-on transistor.

20. The method of claim 19, further comprising:
illuminating the plurality of series-connected current-generating photoelectric devices by supplying a current to one or more light-emitting devices optically coupled to the plurality of series-connected current-generating photoelectric devices.
